(19) United States
(12) Patent Application Publication
(10) Pub. No.: US 2025/0089226 A1
(43) Pub. Date: Mar. 13, 2025

(54) Shielded case for wireless earpieces

(71) Applicant: BRAGI GmbH, München (DE)

(72) Inventors: Veniamin Milevski, München (DE); Diego Bestilleiro Amado, München (DE)

(73) Assignee: BRAGI GmbH, München (DE)

(21) Appl. No.: 18/959,588

(22) Filed: Nov. 25, 2024

Related U.S. Application Data
(63) Continuation of application No. 18/466,631, filed on Sep. 13, 2023, now Pat. No. 12,178,027.
Application No. 18/466,631 is a continuation of application No. 18/049,465, filed on Oct. 25, 2022, now Pat. No. 11,770,918.
Application No. 18/049,465 is a continuation of application No. 17/136,357, filed on Dec. 29, 2020, now Pat. No. 11,497,150.
Application No. 17/136,357 is a continuation of application No. 15/639,661, filed on Jun. 30, 2017, now Pat. No. 10,888,039.
(60) Provisional application No. 62/358,779, filed on Jul. 6, 2016.

(51) Int. Cl. H05K 9/00; H04R 1/10

(52) U.S. Cl. CPC H05K 9/0007; H04R 1/1025; H05K 9/0086; H04R 1/10; H04R 1/1016; H04R 2420/07; H04R 2460/17

(57) ABSTRACT

An apparatus includes a ear piece case housing, a receptacle within the ear piece case housing and configured to hold an earpiece, an earpiece connector at the receptacle and configured to electrically connect with the earpiece, and electromagnetic shielding materials integrated into the ear piece case housing to electromagnetically isolate the earpiece while the earpiece is contained within the case housing. The ear piece case housing may include a charger and a removable slide cover adapted for sliding over the charger.

### PRIORITY STATEMENT

This application is a continuation of U.S. Non-Provisional patent application Ser. No. 18/466,631, filed Sep. 13, 2023, which is a continuation of U.S. Non-Provisional patent application Ser. No. 18/049,465, filed Oct. 25, 2022 now U.S. Pat. No. 11,770,918, which is a continuation of U.S. Non-Provisional patent application Ser. No. 17/136,357, filed Dec. 29, 2020 now U.S. Pat. No. 11,497,150, which is a continuation of U.S. Non-Provisional patent application Ser. No. 15/639,661, filed Jun. 30, 2017 now U.S. Pat. No. 10,888,039, which claims priority to U.S. Provisional Patent Application 62/358,779, filed on Jul. 6, 2016, and all entitled Shielded case for wireless earpiece, hereby incorporated by reference in their entirety.

### FIELD OF THE INVENTION

The present invention relates to wireless earpieces and accessories. More particularly, but not exclusively, the present invention relates to a shielded case for wireless earpieces.

### BACKGROUND

Wireless earpieces may be placed within a case when not in use. However, there may be problems with doing so. For example, when not in use it may be desirable to not permit wireless connections between the earpieces and other devices. Therefore, what is needed are new improved cases for wireless earpieces.

### SUMMARY

Therefore, it is a primary object, feature, or advantage of the present invention to improve over the state of the art.

It is a further object, feature, or advantage of the present invention to shield a smart case from magnetic radiation.

It is a still further object, feature, or advantage of the present invention to shield a smart case from radio frequencies.

Another object, feature, or advantage is to screen out high wavelength electromagnetic radiation.

In one implementation, an apparatus includes a smart case with at least one receptacle configured to hold an earpiece, and a slide cover composed of shielding materials to encase the smart case.

One or more of the following features may be included. The slide cover may be composed of magnetic shielding materials or RF shielding materials. A liner may be attached to the inside of the slide cover which may be scratch-resistant, magnetically shielded, RF shielded, or a combination of one or more of the aforementioned. A metal mesh configured to restrict one or more wavelengths may be attached to the inside of the slide cover, which may be printed onto the slide cover. The liner may be layered over the metal mesh.

One or more of the following features may be included. The slide cover may be include magnetic shielding materials, RF shielding materials, or both. A liner may be attached to the inside of the smart case, which may be scratch-resistant, magnetically shielded, RF shielded, or a combination of one or more of the aforementioned. A metal mesh configured to restrict one or more wavelengths may be attached to the inside of the slide cover, which may be printed onto the slide cover by vapor deposition, additive manufacturing processes such as 3D printing, or any number of other ways. A liner may be layered over the metal mesh, which may be scratch-resistant, magnetically shielded, RF shielded, or a combination of one or more of the aforementioned.

According to another aspect, an apparatus includes an ear piece case housing, a receptacle within the ear piece case housing and configured to hold an earpiece, an earpiece connector at the receptacle and configured to electrically connect with the earpiece, and electromagnetic shielding materials integrated into the ear piece case housing to electromagnetically isolate the earpiece while the earpiece is contained within the case housing. The ear piece case housing may include a charger and a removable slide cover adapted for sliding over the charger.

According to another aspect, an earpiece case housing includes a charger and a removable slide cover adapted for sliding over the charger, a first receptacle within the ear piece case housing and configured to hold a first earpiece, a second receptacle within the ear piece case housing and configured to hold a second earpiece, a first earpiece connector at the receptacle and configured to electrically connect with the first earpiece, a second earpiece connector at the receptacle and configured to electrically connect with the second earpiece, and electromagnetic shielding materials integrated into the ear piece case housing to electromagnetically isolate the earpiece while the earpiece is contained within the case housing.

One or more of these and/or other objects, features, or advantages of the present invention will become apparent from the specification and claims that follow. No single embodiment need provide each and every object, feature, or advantage. Different embodiments may have different objects, features, or advantages. Therefore, the present invention is not to be limited to or by an object, feature, or advantage stated herein.

### BRIEF DESCRIPTION OF THE DRAWINGS

FIG. 1 includes a view of an earpiece case housing have a slide cover and a charger.

FIG. 2 illustrates the charger adapted for receiving earpieces.

FIG. 3 illustrates one example of the slide cover.

FIG. 4 illustrates a cross-section of the earpiece case housing including a liner and a filter.

### DETAILED DESCRIPTION

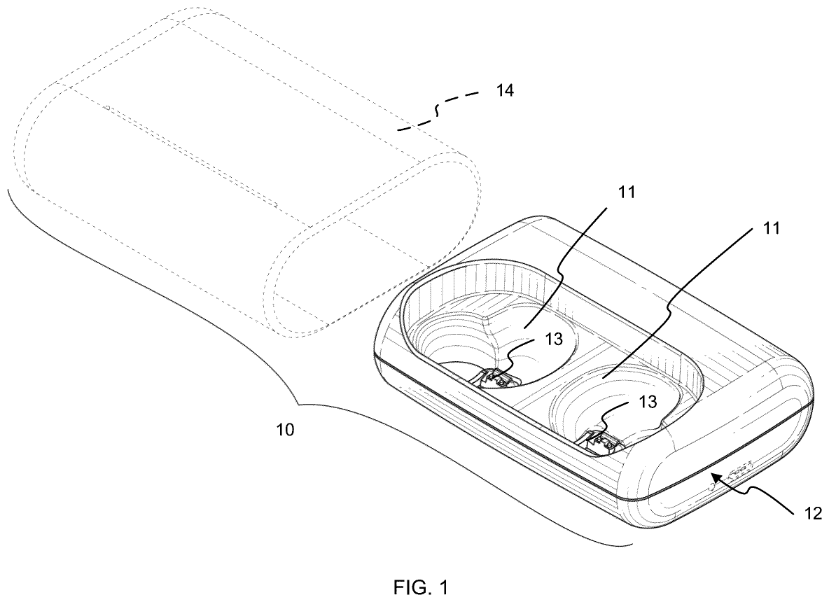

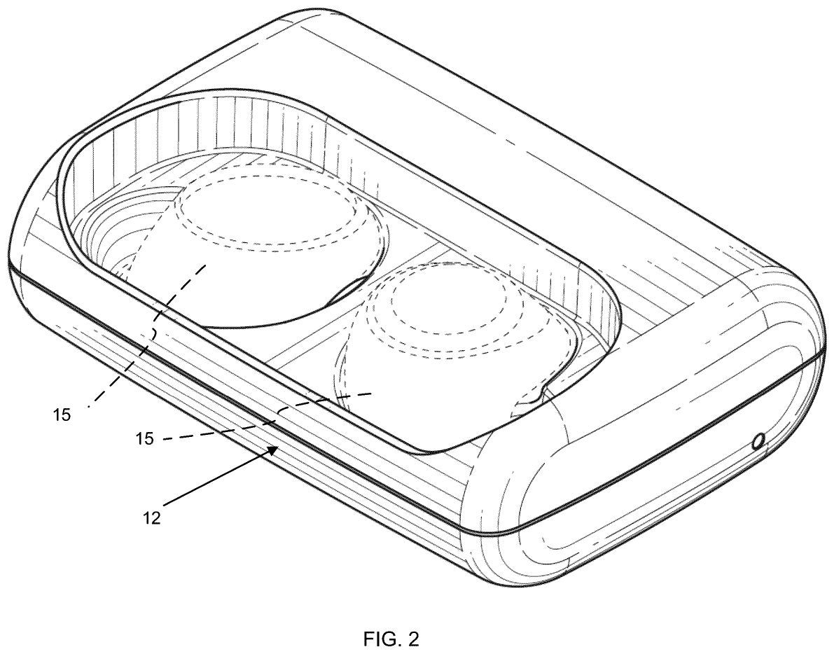

The present invention provides an earpiece case with shielding. FIG. 1 illustrates one embodiment of the earpiece case housing 10 which includes a charger 12 and a slide cover 14. The charger 12 includes receptacles 11 for placing left and right earpieces. When the left and right earpieces (not shown) are placed within the charger 12, connections are made between contact points on the earpieces and connectors 13. The connectors 13 may be magnetic connectors to make it easier for a user to properly connect the earpieces to the earpiece case housing. Thus, when the earpieces are placed in the charger 12 the earpieces may be charged by the charger 12 such as by using a battery also disposed within the charger 12, or through connecting the charger 12 to a power source such as a USB power source, or other type of power source. In addition, data may be communicated through the connectors 13 as well for various purposes including to upload data to or download data from the earpieces. FIG. 2 further illustrates the charger 12 configured to receive earpieces 15 into its receptacles.

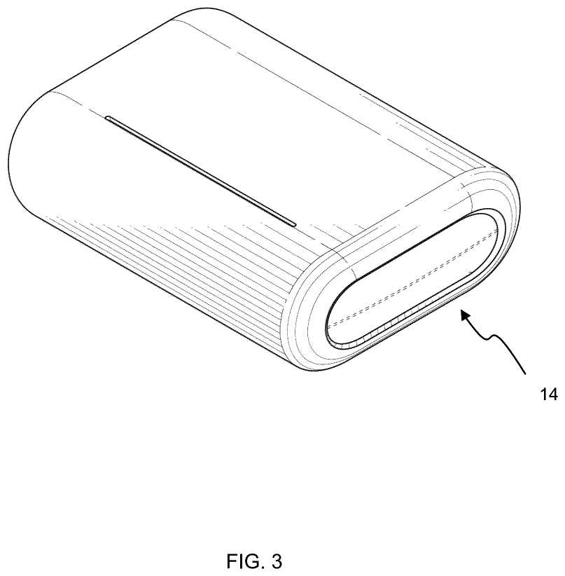

FIG. 3 illustrates the slide cover 14. The slide cover 14 includes shielding which can serve several different functions. First, the magnetic shielding may be used to shield objects outside of the earpiece case from any effects of the magnetic connectors 13. Second, the shielding may be used to shield the wireless earpieces which may include one or more radio transceivers in at least one of the earpieces from connecting with other devices while the earpieces are within the earpiece case and not in use. Thus, for example, while the earpieces are within the earpiece case, a mobile phone or computer which is sometimes paired via Bluetooth the one or both of the earpieces would not be able to find the earpieces or try to connect with the earpieces or vice versa.

The slide cover 14 may be constructed in various ways in order to provide shielding. For example, the slide cover 14 may be formed from a high permeability such as an alloy having high nickel content (e.g. 50 percent or more). Examples of alloys which may be used include Permalloy and Mu-Metal. Of course, any number of other materials may be used provided they allow for adequate shielding. The slide cover 14 may also include mesh material to provide RF shielding and/or a liner.

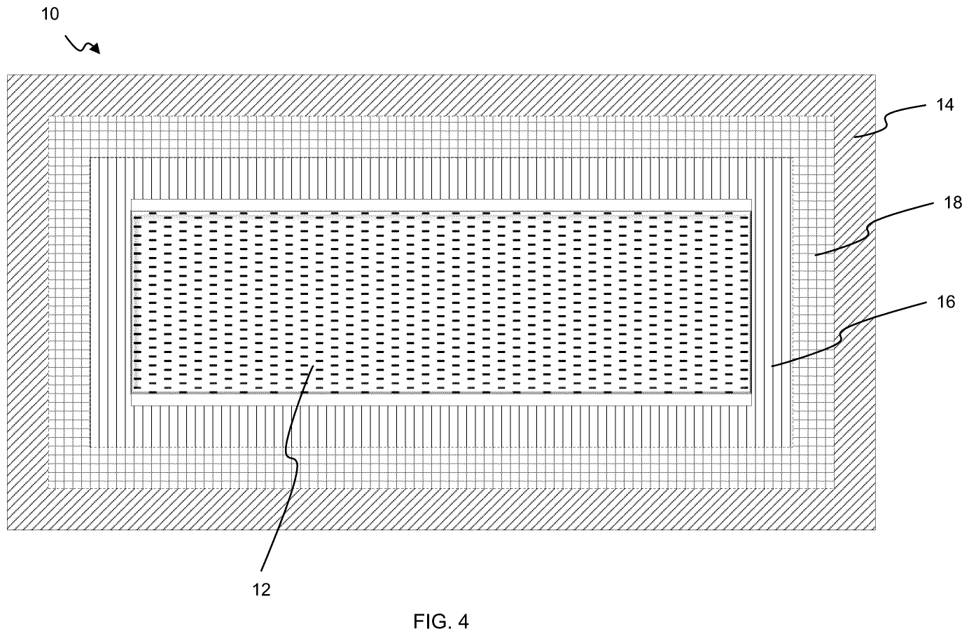

FIG. 4 shows a cross-sectional view of the ear piece case 10, including the charger 12 and the slide cover 14. The charger 12 may be placed, positioned, or disposed within the slide cover 14 and may be removed from or placed into the slide cover 14 as needed by a user. The charger 12 may be configured to hold one or more earpieces, and may have one or more electrical components installed that may be used to power, operate, or otherwise control an earpiece. The slide cover 12 may be manufactured using scratch-resistant materials, or any materials that would reduce the likelihood of becoming damaged, and may be configured to withstand the force of impact from falls without becoming damaged to the point of inoperability. In addition, the charger 12 may have magnetic and radiofrequency (RF) shielding in addition to any shielding the slide cover 14 provides in order to improve the operability of an earpiece. For example, one or more ends of the charger 12 may have shielding. The charger 12 may also be readily transportable by the user. The slide cover 14 may be configured to encase the charger 12. The slide cover 14 may be composed of scratch-resistant materials, magnetic shielding materials, and/or RF shielding materials depending on the requirements of a prospective user.

The slide cover 14 may have a liner 16 attached to the inside of the slide cover 14 and/or a metal mesh 18 attached to the inside of the slide cover 14, with the liner 16 layered over the metal mesh 18. The liner 16, may include shielding materials, such as magnetic shielding materials or RF shielding materials. Where used, a metal mesh 18 may be attached to the slide cover 14 wherein the apertures are sized, shaped, positioned, or otherwise configured to block EM radiation such as radio waves, especially radio signals at frequencies associated with Bluetooth, or matching the frequencies of the wireless transceiver(s) of the earpiece(s).

The charger 12 may also have one or more additional components installed within, including, but not limited to, a processor, a battery, a data storage device, one or more sensors, a display, or one or more transceivers. The processor may be used to monitor or control one or more earpieces present within the earpiece case housing. The battery may be used to power the processor and other components present within the earpiece case housing or power one or more earpieces present within one or more receptacles of the earpiece case housing. The data storage device may be used to store programs used to modify, monitor, operate, or otherwise control one or more earpieces present in the earpiece case housing. One or more transceivers may be used to communicate with the earpiece case housing when the case is not shielded. One or more sensors may be used to determine when the slide cover 14 removed and potentially terminate the powering of any earpieces present within the earpiece case housing or even to turn one or more of the earpieces on. The charger may also include one or more status lights and/or one or more power or data connectors. The status light may show the status of the power within the earpiece case housing. For example, the status light may illuminate green when the charger is fully charged, yellow when the charger is less than fully charged, and red when the smart case is in need of power. The status light need not have more than one color, however; a single color light that conveys information through changes in luminescence intensity or intermittent flashing may also be used. For example, a solid light may represent a fully charged battery, a light of lower luminescence may represent a less than fully charged battery, wherein the luminescence gradually falls in proportion to the battery level, and a flashing light may represent that the battery needs to be recharged, wherein the flashing may become faster and more pronounced the closer the battery is to running out of power. The power source connector may be configured to connect any type of electrical wiring that is suitable for the earpiece case housing.

According to another embodiment instead of a slide cover, the smart case may be of a clamshell design. One or more hinges may be present to hinge a top portion of the smart case to a bottom of the smart case. The case housing includes at least one receptacle configured to hold an earpiece and at least one connector for each earpiece. The shielding materials may be integrated into smart case to provide for shielding. The case housing may include a first portion and a second portion wherein the first portion and the second portion are moveable with respect to each other to define an open position and a closed position. One of the first portion and the second portion may be a slide cover. The other of the first portion and the second portion may be a charger. Alternatively, the first portion and the second portion may be, for example, a top portion of a clamshell case and a bottom portion of a clamshell case. Of course, any number of other types of configurations are contemplated.

Therefore, a smart case for earpieces has been shown and described which includes magnetic shielding. Although various embodiments have been described, the present invention contemplates numerous options, additions, and variations.

What is claimed is:

1. An apparatus comprising:
an earpiece case housing comprising a charger and a cover, the charger having a top and an opposite bottom and first and second opposite sides;
a first receptacle within a leftmost recess within the top of the charger, the first receptacle configured to hold a first earpiece for fitting to a left ear;
a second receptacle within a rightmost recess within the top of the charger and spaced apart from the first receptacle, the second receptacle configured to hold a second earpiece for fitting to a right ear while the first receptacle holds the first earpiece without contact between the first earpiece and the second earpiece;
a first magnetic earpiece connector at the first receptacle and configured to electrically connect with the first earpiece;
a second magnetic earpiece connector at the second receptacle and configured to electrically connect with the second earpiece;
a processor disposed within the earpiece case housing;
a data storage device disposed within the earpiece case housing;
wherein the processor is configured to: monitor at least one of the first earpiece and the second earpiece through the respective magnetic earpiece connector; execute one or more programs stored in the data storage device to control operation of at least one of the first earpiece and the second earpiece;
wherein in an open position, the cover is sufficiently separated from the charger to provide access to the first receptacle and the second receptacle for inserting or removing the first earpiece from the first receptacle and inserting or removing the second earpiece from the second receptacle;
wherein in a closed position the cover is positioned over the first receptacle and the second receptacle;
a battery disposed within the earpiece case housing;
a power source connector on the earpiece case housing for electrically connected to a power source; and
electromagnetic shielding materials integrated into the charger of the earpiece case housing.

2. The apparatus of claim 1 wherein the cover comprises a nickel alloy.

3. The apparatus of claim 2 wherein the nickel alloy comprises at least 50 percent nickel.

4. The apparatus of claim 1 wherein the cover comprises a liner.

5. The apparatus of claim 4 wherein the cover comprises a layer of metal mesh as the electromagnetic shielding material.

6. The apparatus of claim 5 wherein the layer of metal mesh is printed onto an inside surface of the cover.

7. The apparatus of claim 1 wherein the cover comprises a liner and a layer of metal mesh.

8. The apparatus of claim 1 wherein the cover is slidably movable between the open position and the closed position.

9. The apparatus of claim 1 further comprising at least one status light for showing status of power of the battery disposed within the earpiece case housing.

10. The apparatus of claim 1 wherein the power source connector is a USB port.

11. The apparatus of claim 1 further comprising a transceiver disposed within the earpiece case housing.

12. The apparatus of claim 1 further comprising a display of the earpiece case housing operatively connected to the processor.

13. An apparatus comprising:
an earpiece case housing comprising a charger and a cover, the charger having a top and an opposite bottom and first and second opposite sides;
a first receptacle within a recess within the top of the charger, the first receptacle configured to hold a first earpiece;
a second receptacle within the recess within the top of the charger and spaced apart from the first receptacle, the second receptacle configured to hold a second earpiece while the first receptacle holds the first earpiece without contact between the first earpiece and the second earpiece;
a first magnetic earpiece connector at the first receptacle and configured to electrically connect and communicate data with the first earpiece;
a second magnetic earpiece connector at the second receptacle and configured to electrically connect and communicate the data with the second earpiece;
electromagnetic shielding materials integrated into the earpiece case housing to electromagnetically shield the first earpiece and the second earpiece while the first earpiece and the second earpiece are contained within the earpiece case housing;
a processor disposed within the earpiece case housing;
a data storage device disposed within the earpiece case housing;
wherein the processor is configured to: monitor at least one of the first earpiece and the second earpiece through the respective magnetic earpiece connector; execute one or more programs stored in the data storage device to control operation of at least one of the first earpiece and the second earpiece.

14. The apparatus of claim 13 wherein the cover comprises a layer of metal mesh to provide electromagnetic shielding.

15. The apparatus of claim 14 wherein the layer of metal mesh is printed on an inside surface of the slide cover.

16. The apparatus of claim 14 wherein the cover further comprises a liner inside of the layer of metal mesh.

17. The apparatus of claim 13 wherein the cover is slidably movable between an open position and a closed position.

18. The apparatus of claim 13 further comprising a transceiver disposed within the earpiece case housing.

19. The apparatus of claim 13 further comprising a display of the earpiece case housing operatively connected to the processor.
